(19) United States
(12) Patent Application Publication
(10) Pub. No.: US 2026/0070173 A1
(43) Pub. Date: Mar. 12, 2026

(54) BONDING APPARATUS, BONDING METHOD, AND ARTICLE MANUFACTURING METHOD

(71) Applicant: CANON KABUSHIKI KAISHA, Tokyo (JP)

(72) Inventor: MASAHIRO KIMURA, Tochigi (JP)

(21) Appl. No.: 19/317,744

(22) Filed: Sep. 3, 2025

(30) Foreign Application Priority Data
Sep. 10, 2024 (JP) 2024-156836

(51) Int. Cl. B23Q 3/00; B23Q 3/18

(52) U.S. Cl. CPC B23Q 3/007; B23Q 3/186

(57) ABSTRACT

A bonding apparatus that executes a bonding process of bonding a second member to a plurality of regions of a first member, comprising a scope, a bonding mechanism configured to bond each of a plurality of second members to one of the plurality of regions, and a controller configured to execute a decision process of deciding positions of the plurality of regions by measuring, using the scope, a position of a selected region among the plurality of regions and control the bonding process based on the positions of the plurality of regions. The controller decides to re-execute the decision process in accordance with a situation of the bonding process.

### BACKGROUND

### Field of the Technology

The present disclosure relates to a bonding apparatus, a bonding method, and an article manufacturing method.

### Description of the Related Art

Japanese Patent Laid-Open No. 2023-77928 describes a bonding apparatus that bonds a second object to a first object. The bonding apparatus described in Japanese Patent Laid-Open No. 2023-77928 includes a first camera that captures an image of the first object, and a second camera that captures an image of the second object, and positions the second object to a bonding target location of the first object based on the output of the first camera and the output of the second camera.

When acquiring information of the positions of a plurality of bonding target regions on a substrate by measurement and, after that, bonding a die to the plurality of bonding target regions in accordance with the information, if the position of the substrate changes or the substrate is deformed upon bonding, the die cannot be bonded to a correct position on the substrate.

### SUMMARY

The present disclosure provides a technique advantageous in accurate bonding.

A first aspect of the present disclosure provides a bonding apparatus that executes a bonding process of bonding a second member to a plurality of regions of a first member, comprising: a scope; a bonding mechanism configured to bond each of a plurality of second members to one of the plurality of regions; and a controller configured to execute a decision process of deciding positions of the plurality of regions by measuring, using the scope, a position of a selected region among the plurality of regions and control the bonding process based on the positions of the plurality of regions, wherein the controller decides to re-execute the decision process in accordance with a situation of the bonding process.

A second aspect of the present disclosure provides an article manufacturing method comprising: bonding a second member to a first member using a bonding apparatus as defined as the first aspect to obtain a bonded article; and processing the bonded article to obtain an article.

A third aspect of the present disclosure provides a bonding method comprising: executing a decision process of deciding positions of a plurality of regions of a first member by measuring, using a scope, a position of a selected region among the plurality of regions; executing a bonding process of bonding one of a plurality of second members to each of the plurality of regions based on the positions of the plurality of regions decided by the decision process; and re-executing the decision process in accordance with a situation of the bonding process.

A fourth aspect of the present disclosure provides an article manufacturing method comprising: bonding a second member to a first member in accordance with a bonding method to obtain a bonded article, wherein the bonding method comprises: executing a decision process of deciding positions of a plurality of regions of the first member by measuring, using a scope, a position of a selected region among the plurality of regions; executing a bonding process of bonding one of a plurality of second members to each of the plurality of regions based on the positions of the plurality of regions decided by the decision process; and re-executing the decision process in accordance with a situation of the bonding process; and processing the bonded article to obtain an article.

Features of the present disclosure will become apparent from the following description of embodiments with reference to the attached drawings. The following description of embodiments are described by way of example.

### BRIEF DESCRIPTION OF THE DRAWINGS

The accompanying drawings, which are incorporated in and constitute a part of the specification, illustrate embodiments of the present disclosure, and together with the description, serve to explain the principles of the embodiments.

FIG. 1 is a view schematically showing the configuration of a bonding apparatus according to an embodiment;

FIG. 2 is a view schematically showing the configuration of a substrate stage;

FIG. 3 is a schematic view for explaining a die;

FIG. 4 is a flowchart showing the procedure of a bonding process; and

FIG. 5 is a flowchart showing a method of determining the necessity of alignment measurement.

### DESCRIPTION OF THE EMBODIMENTS

Hereinafter, embodiments will be described in detail with reference to the attached drawings. Note, the following embodiments are not intended to limit the scope of the claims. Multiple features are described in the embodiments, but it is not the case that all such features are required, and multiple such features may be combined as appropriate. Furthermore, in the attached drawings, the same reference numerals are given to the same or similar configurations, and redundant description thereof is omitted.

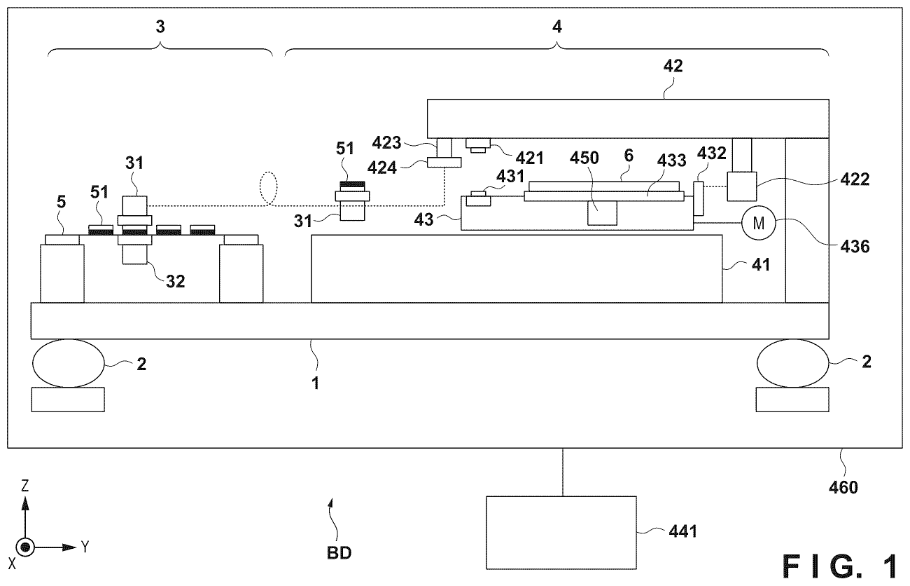

FIG. 1 is a view schematically showing the configuration of a bonding apparatus BD according to an embodiment. The bonding apparatus BD can be configured to bond a second member to a plurality of regions on a first member. In the specification and the accompanying drawings, directions will be indicated on an XYZ coordinate system in which a horizontal surface is defined as the X-Y plane. Generally, a substrate 6 that is the first member is placed on a substrate stage 43 so that the surface of the substrate 6 becomes parallel to the horizontal surface (X-Y plane). In the following description, directions orthogonal to each other within a plane along the surface of the substrate 6 placed on the substrate stage 43 will be defined as the X-axis and the Y-axis, and a direction perpendicular to the X-axis and the Y-axis will be defined as the Z-axis. Also, in the following description, directions parallel to the X-axis, the Y-axis, and the Z-axis in the XYZ coordinate system will be referred to as the X direction, the Y direction, and the Z direction, respectively.

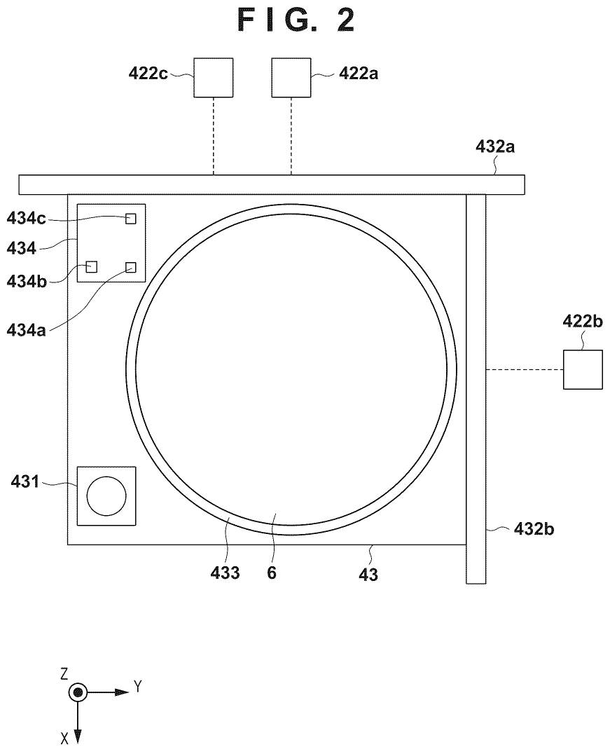

In the specification and the accompanying drawings, a suffix attached to a reference numeral is used to indicate a specific one of those represented by the reference numeral. For example, the bonding apparatus shown in FIG. 1 comprises a bar mirror 432, and the bar mirror 432 can comprise direction-specific bar mirrors 432a and 432b (see FIG. 2), which will be described later. When a direction-specific bar mirror needs to be specified, a reference numeral with a suffix such as the bar mirror 432a or the bar mirror 432b is used. In contrast, when a bar mirror need not be specified, a reference numeral without a suffix such as the bar mirror 432 is used.

The first member can be a substrate (wafer) on which a semiconductor device is manufactured. The second member can be a diced die such as a semiconductor device. However, the first member and the second member are not limited to these. For example, the first member can be a silicon interposer obtained by forming wirings on a silicon substrate, a glass interposer obtained by forming wirings on a glass substrate, or an organic interposer obtained by forming wirings on an organic panel (PCB). Alternatively, the first member may be a member obtained by bonding a die already comprising a semiconductor device to a substrate on which a semiconductor device is manufactured. Alternatively, the second member may be a stacked body of a plurality of already diced dies, a small piece of a material, an optical element, a MEMS, or the like.

In addition, the method of bonding the first member and the second member is not limited to a specific bonding method. For example, an arbitrary bonding method may be employed, such as bonding using an adhesive, temporary bonding using a temporary adhesive, bonding by hybrid bonding, atomic diffusion bonding, vacuum bonding, and bump bonding. Various temporary bonding and permanent bonding methods are available.

Industrial application examples of the bonding apparatus BD according to the present disclosure will be explained below.

The first application example is manufacturing of a stacked memory. In a case where the bonding apparatus is applied to manufacturing of a stacked memory, the first member can be a substrate on which a memory that is a semiconductor device is manufactured, and the second member can be a diced memory die. For example, when stacking eight layers, in bonding of the eighth layer, the first member is a substrate on which six layers of memory dies are already bonded to the substrate. Note that the top layer is sometimes a driver die that drives the memory.

The second application example is heterogeneous integration of a processor. The mainstream of conventional processors is a SoC in which a logic circuit and an SRAM are formed in one semiconductor element. To the contrary, in heterogeneous integration, elements are manufactured on separate substrates by applying processes optimal for the respective elements and bonded, thereby manufacturing a processor. This can implement cost reduction and yield improvement of processors. In a case where the bonding apparatus BD is applied to heterogeneous integration, the first member can be a substrate on which a memory that is a semiconductor device is manufactured, and the second member can be a die diced after probing, such as an SRAM, an antenna, or a driver. In general, different dies are sequentially bonded to a substrate. For example, if bonding of an SRAM is performed first, when bonding the die next to the SRAM, the first member is a logic substrate to which the SRAM die is bonded.

The third application example is 2.5D bonding using a silicon interposer. The silicon interposer is a silicon wafer on which wirings are formed. The 2.5D bonding is a method of bonding diced dies using the silicon interposer and electrically connecting the dies. In a case where the bonding apparatus BD is applied to die bonding of a silicon interposer, the first member can be a silicon interposer obtained by forming wirings on a silicon wafer, and the second member can be a diced die. Generally, a plurality of types of dies are bonded to a silicon interposer, so the first member comprises a silicon interposer to which some dies are already bonded.

The fourth application example is 2.1D bonding using an organic interposer or a glass interposer. The organic interposer is an organic panel (a PCB substrate or a CCL substrate) used as a package substrate, on which wirings are formed. The glass interposer is a glass panel on which wirings are formed. The 2.1D bonding is a method of bonding diced dies to the organic interposer or the glass interposer and electrically bonding the dies by the wirings on the interposer. In a case where the bonding apparatus BD is applied to die bonding to the organic interposer, the first member can be an organic panel on which wirings are formed, and the second member can be a diced die. In a case where the bonding apparatus BD is applied to die bonding of the glass interposer, the first member can be a glass panel on which wirings are formed, and the second member can be a diced die. In general, a plurality of types of dies are bonded to an organic interposer or a glass interposer, so the first member comprises an organic interposer or a glass interposer to which some dies are already bonded.

The fifth application example is heterogeneous substrate bonding. For example, in an infrared image sensor, InGaAs is known as a high-sensitivity material. There is proposed a method of manufacturing a high-sensitivity high-speed infrared image sensor using InGaAs for a sensor unit that receives light, and using silicon capable of forming a high-speed processing die for a logic circuit that extracts data. However, for InGaAs crystal, only substrates whose diameter is as small as 4 inches are mass-produced, which is smaller than a mainstream 300-mm silicon wafer. Hence, there is proposed a method of bonding a diced InGaAs substrate onto a 300-mm silicon wafer on which a logic circuit is formed. In this manner, bonding of substrates different in material and size is called heterogeneous substrate bonding. In the application of the bonding apparatus BD to heterogeneous substrate bonding, the first member can be a substrate with a large diameter such as a silicon wafer, and the second member can be a small piece of a material such as InGaAs. Note that a small piece of a material is a slice of a crystal and is desirably cut into a rectangular shape.

To provide a detailed example, the following description will be made assuming that the first member is a substrate (wafer) on which a semiconductor device is manufactured, and the second member is a diced die comprising a semiconductor device.

The bonding apparatus BD can comprise a pickup mechanism 3 and a bonding mechanism 4. The pickup mechanism 3 and the bonding mechanism 4 can be mounted on a base 1 damped by a mount 2. The bonding apparatus BD can be configured to bond a diced die 51 that is a second member to each of a plurality of regions on the substrate 6 that is a first member. The die 51 can be provided in such a form that, for example, dies 51 are arranged on a dicing tape provided on a dicing frame 5. In the example shown in FIG. 1, the pickup mechanism 3 and the bonding mechanism 4 are mounted on one base 1. However, the pickup mechanism 3 and the bonding mechanism 4 may be mounted on separate bases.

The pickup mechanism 3 can comprise a pickup head 31 and a release head 32. The release head 32 peels the dicing tape from the die 51, and the pickup head 31 picks up the die 51 from which the dicing tape is peeled by the release head 32. The pickup head 31 rotates about the Y-axis such that the die 51 picked up faces upward and transfers the die 51 to a bonding head 423. The bonding head 423 can comprise a suction mechanism 424 configured to suck and hold the die 51.

The bonding mechanism 4 can comprise a stage base 41, an upper base 42, the substrate stage 43, and a stage driving mechanism 436. The substrate stage 43 can be mounted on the stage base 41. The substrate stage 43 can be, for example, translationally driven in the X and Y directions and rotationally driven about the Z-axis by the stage driving mechanism 436 comprising a motor such as a linear motor. The substrate stage 43 may be configured to be rotationally driven about the X-axis and/or tilt-driven about the Y-axis by the stage driving mechanism 436. Note that instead of rotationally driving and/or tilt-driving the substrate stage 43, the bonding head 423 may be rotationally driven and/or tilt-driven.

A die observation camera 431 (second scope) is mounted on the substrate stage 43. The die observation camera 431 comprises an image capturing device, and an optical system that forms an image of an image capturing target on the imaging plane of the image capturing device. The die observation camera 431 can be configured to measure, for example, the position of a feature point of the die 51 that is the second member, the outer dimensions of the die 51, and the distances of a plurality of points on a measurement surface in the height direction (Z direction). The position, the outer dimensions, and the flatness of the die 51 held by the bonding head 423 can thus be measured using the die observation camera 431.

The bar mirror 432 can be arranged on a side surface of the substrate stage 43. The bar mirror 432 can function as the target of an interferometer 422 that is a measuring device. Also, a substrate chuck 433 that chucks or holds the substrate 6 that is the first member can be mounted on the substrate stage 43. The chuck method of the substrate chuck 433 may be vacuum suction, electrostatic chucking, or any other method.

The upper base 42 can support a substrate observation camera 421 (scope). The substrate observation camera 421 can be configured to measure, for example, the position of a feature point on the substrate 6 that is the first member and the distances of a plurality of points in the height direction. The positions of a plurality of regions of bonding targets of the substrate 6 and the flatness can thus be measured. The substrate observation camera 421 comprises an image capturing device, and an optical system that forms an image of an image capturing target object on the imaging plane of the image capturing device. Also, the upper base 42 can support the interferometer 422 that is a measuring device configured to measure the position of the substrate stage 43, and the bonding head 423 configured to hold the die 51 that is the second member transferred from the pickup head 31. The substrate observation camera 421 can be, for example, a camera that uses infrared light as a measurement light source. The substrate observation camera 421 can be configured to measure, for example, an element pattern and/or a mark formed on the surface of the substrate 6 or inside the substrate 6.

A lifting mechanism 450 can be mounted on the substrate stage 43. The lifting mechanism 450 can be configured to drive the substrate chuck 433 in the Z direction to bond the die 51 to a bonding target region on the substrate 6. The lifting mechanism 450 may be configured to drive the substrate stage 43 in the Z direction. An operation for bonding can comprise an approximating operation of moving the bonding head 423 and the substrate chuck 433 close to each other so as to bring the die 51 and the substrate 6 into contact with each other, and a separating operation of moving the bonding head 423 and the substrate chuck 433 away from each other after the approximating operation. The lifting mechanism 450 can perform the approximating operation by driving the substrate chuck 433 in the +Z direction, and perform the separating operation by driving the substrate chuck 433 in the −Z direction. Alternatively, the approximating operation may be performed by moving the bonding head 423 in the +Z direction, and the separating operation may be performed by moving the bonding head 423 in the −Z direction. Alternatively, bonding may be performed by moving both the bonding head 423 and the substrate chuck 433 in the Z direction. That is, the lifting mechanism 450 is an example of a relative driving mechanism that relatively drives the bonding head 423 and the substrate chuck 433 so as to change the interval between the die 51 and the substrate 6. When driving the substrate chuck 433 by such a relative driving mechanism, the position of the substrate chuck 433 in the Z direction is feedback-controlled in real time while measured by the interferometer 422.

In the above description, the pickup head 31 rotates and transfers a die to the bonding head 423. However, it is also possible to provide two or more die holders, relay a die between the die holders, and then transfer it to the bonding head 423. Alternatively, by the driving mechanism of the bonding head 423, the bonding head 423 may be moved to the position to receive the die 51. Also, to improve productivity, a plurality of pickup mechanisms, a plurality of pickup heads, a plurality of release heads, and a plurality of bonding heads may be arranged.

A controller 441 comprehensively controls the constituent elements of the bonding apparatus BD. The controller 441 can be formed by, for example, a PLD (a short for Programmable Logic Device) such as an FPGA (a short for Field Programmable Gate Array), an ASIC (a short for Application Specific Integrated Circuit), a general-purpose or dedicated computer with programs installed therein, or a combination of some or all of these. The controller 441 may be arranged in the internal space of a housing 460 of the bonding apparatus BD or outside the housing 460. The controller 441 arranged outside the housing 460 of the bonding apparatus BD may be implemented by, for example, a computer functioning as a control server connected to the main body (a portion stored in the housing 460) of the bonding apparatus BD via a network.

FIG. 2 is a view showing the substrate stage 43 viewed in a positive Z-axis direction. The substrate 6 can be held by the substrate chuck 433. The bar mirror 432 can comprise at least the two bar mirrors 432a and 432b so that the positions of the substrate 6 in the X direction and the Y direction and the rotational amount about the Z-axis can be measured. The bar mirror 432a is the target of interferometers 422a and 422c configured to measure the position in the X direction. The rotation amount about the Z-axis can be measured based on the difference between measurement values obtained by the interferometers 422a and 422c. The bar mirror 432b is the target of an interferometer 422b configured to measure the position in the Y direction. The interferometer 422 can measure the positions of the substrate stage 43 in the X direction and the Y direction and the rotational amount about the Z-axis in real time. The controller 441 can feedback-control the stage driving mechanism 436 in real time based on the result of measurement by the interferometer 422 and accurately position the substrate stage 43. In the above-described way, positioning of the substrate 6 or the substrate stage 43 can be performed by feedback control based on accurate position measurement by the interferometer that is a measuring device.

A reference plate 434 on which a plurality of marks (such as marks 434a, 434b, and 434c) are formed can be arranged beside the substrate chuck 433. The reference plate 434 desirably has a low coefficient of thermal expansion and bears marks arranged at high position accuracy. In an example, the reference plate 434 can be a quartz substrate on which marks are formed using a semiconductor lithography process. It is desirable that the reference plate 434 is constituted at the same level as the surface of the substrate 6 and can be observed by the substrate observation camera 421. However, a camera for reference plate observation may separately be constituted. The substrate stage 43 can comprise a coarse moving stage capable of driving in a large range, and a fine moving stage arranged on the coarse moving stage and capable of driving in a small range at high accuracy. In this case, the die observation camera 431, the bar mirror 432, the substrate chuck 433, and the reference plate 434 can be fixed on the fine moving stage to perform accurate positioning.

A method of guaranteeing the origin position, magnification, and X- and Y-axis directions (rotation) of the substrate stage 43 and the orthogonality between the X-axis and the Y-axis using the reference plate 434 will be described below. An image of the mark 434a is captured by the substrate observation camera 421, and the measurement value of the interferometer 422 when the mark 434a is located at the center of the image acquired by the substrate observation camera 421 is defined as the origin of the substrate stage 43. Next, an image of the mark 434b is captured by the substrate observation camera 421, and the direction of the Y-axis of the substrate stage 43 and the magnification in the Y direction are decided based on the measurement value of the interferometer 422 when the mark 434b is located at the center of the image acquired by the substrate observation camera 421. Then, an image of the mark 434c is captured by the substrate observation camera 421, and the direction of the X-axis of the substrate stage 43 and the magnification in the X direction are decided based on the measurement value of the interferometer 422 when the mark 434c is located at the center of the image acquired by the substrate observation camera 421. That is, a direction from the mark 434b of the reference plate 434 toward the mark 434a is defined as the Y direction, a direction from the mark 434c toward the mark 434a is defined as the X direction, and calibration of the directions of the axes and the orthogonality is performed. In addition, calibration can be performed while defining the interval between the mark 434b and the mark 434a as a scale reference in the Y direction and the interval between the mark 434c and the mark 434a as a scale reference in the X direction. The measurement value of the interferometer 422 may vary upon a change of the refractive index of the optical path of the interferometer 422 due to atmospheric pressure variations and temperature variations. Thus, calibration is desirably performed at an arbitrary timing to guarantee the origin position, magnification, rotation, and orthogonality of a positioning mechanism PM that positions the substrate 6. The positioning mechanism PM can comprise the substrate stage 43, the interferometer 422, and the stage driving mechanism 436. To reduce variations of the measurement value of the interferometer 422, the substrate stage 43 can be arranged in a temperature-controlled chamber where the temperature is controlled within the internal space of the temperature-controlled chamber.

In place of the configuration in which the image of the reference plate 434 on the substrate stage 43 is captured by the substrate observation camera 421, a configuration in which the reference plate 434 is attached to the upper base 42, and the image of the reference plate 434 is captured by the die observation camera 431 may be employed. This configuration can also guarantee the origin position, magnification, rotation, and orthogonality of the positioning mechanism comprising the substrate stage 43, the interferometer 422, and the stage driving mechanism 436.

Alternatively, in place of the configuration in which the image of the reference plate 434 is captured to perform calibration, for example, a configuration in which calibration is performed by an abutment operation against the reference surface may be employed. Alternatively, accurate positioning may be performed using a position measurement unit such as a white interferometer for which an absolute value is guaranteed.

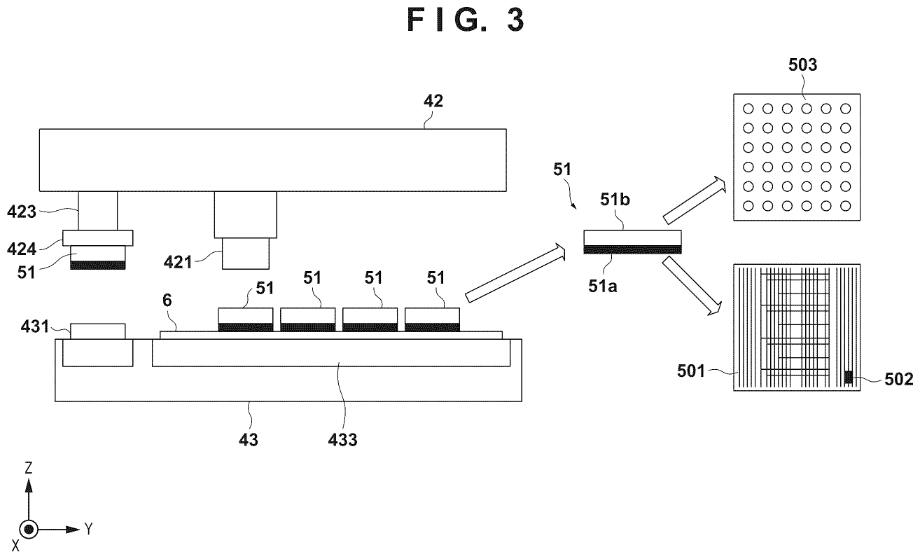

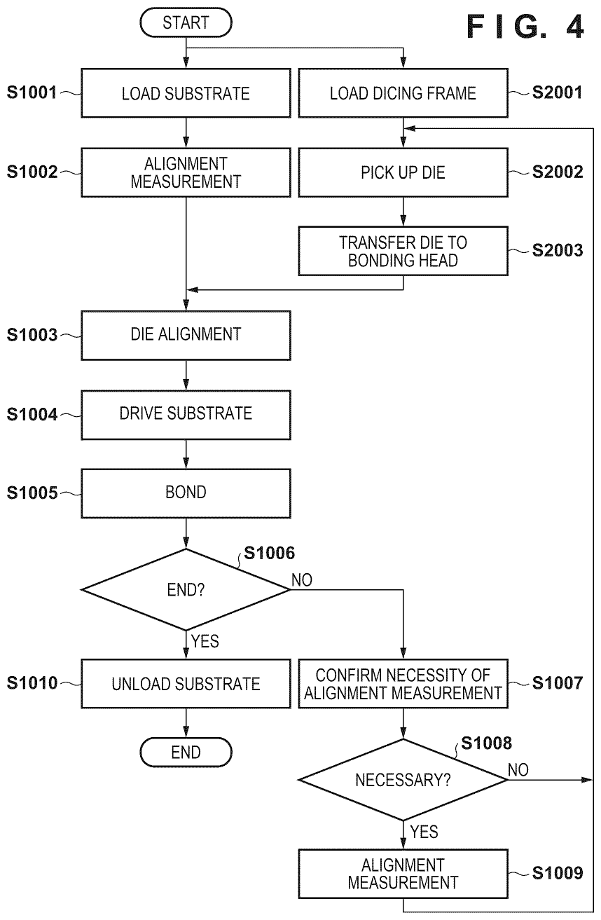

A bonding method according to the first embodiment will be described below with reference to FIGS. 3 and 4. FIG. 3 is a view exemplifying the measurement surface of the die 51 that is the second member. FIG. 4 is a flowchart showing the procedure of the bonding method. In FIG. 3, the direction to the near side from the sheet surface is defined as the X direction, a right direction on the sheet surface is defined as the Y direction, and an upper direction on the sheet surface is defined as the Z direction. The die 51 comprises a bonding surface 51a, and a non-bonding surface 51b that is the surface on the opposite side. The bonding surface 51a can comprise a bonding surface element pattern 501 and a bonding surface alignment mark 502. The non-bonding surface 51b can comprise a through via array pattern 503.

In step S1001, the controller 441 controls a substrate conveyance apparatus (not shown) to load the substrate 6 into the bonding apparatus BD. If a foreign substance adheres to a plurality of regions of bonding targets on the substrate 6 and/or the bonding surface 51a of the die 51, a bonding failure may occur. For this reason, the internal space of the housing 460 of the bonding apparatus BD is a clean space of about class 1. Note that the plurality of regions of bonding targets on the substrate 6 will also be referred to as a plurality of regions of the substrate 6 hereinafter. To keep the cleanliness high, the substrate 6 can also be stored in a container such as a FOUP in which closeness is high and cleanliness is kept high, and loaded from the container to the internal space of the bonding apparatus BD. Also, to increase the cleanliness of the substrate 6, the substrate 6 may be cleaned after it is loaded into the internal space. In addition, a preprocess for bonding can be executed for the substrate 6. For example, when performing bonding using an adhesive, the adhesive can be applied to the substrate 6. When performing bonding by hybrid bonding, a process of activating the surface of the substrate 6 can be executed. A prealignment unit (not shown) can perform adjustment of the rotational direction of the substrate 6 based on a notch or orientation flat formed on the substrate 6, and rough positioning of the substrate 6 based on the outer shape of the substrate 6. After that, the substrate 6 can be held by the substrate chuck 433 on the substrate stage 43.

In step S1002, the controller 441 captures an image of the substrate 6 using the substrate observation camera 421. Focus adjustment of the substrate observation camera 421 may be performed by a focus adjustment mechanism provided inside the substrate observation camera 421 or by driving the substrate 6 in the Z direction using the Z-driving mechanism of the substrate stage 43. Alignment measurement that is a decision process of deciding the positions of the plurality of regions of bonding targets on the substrate 6 can be performed by measuring the position of an alignment mark formed on the substrate 6. If no alignment mark is formed on the substrate 6, alignment measurement can be performed by measuring a feature point whose position can be specified. The controller 441 can measure the position of the feature point by measuring the position of a projected image of the feature point in a captured image with respect to the center of the captured image acquired by image capturing by the substrate observation camera 421.

To accurately measure the position of an alignment mark with respect to a reference point of the bonding apparatus BD, calibration can be executed in advance. In the calibration, the controller 441 can drive the substrate stage 43 based on a command value that is decided such that a mark formed on the reference plate 434 is arranged at a specific position (for example, the center) in the field of view of the substrate observation camera 421. Next, the controller 441 can measures the position of the mark on the reference plate 434 using the substrate observation camera 421. Next, the controller 441 can decide an offset amount used to correct the command value based on the command value given to drive the substrate stage 43 and the position of the mark measured using the substrate observation camera 421. This makes it possible to accurately measure the relative position of the alignment mark with respect to the reference point of the bonding apparatus BD. In general, the reference point of the bonding apparatus BD is often the position of a specific mark of the reference plate 434. However, it may be another place as long as the position can serve as a reference.

Since the measurement range of the interferometer 422 in the rotational direction is narrow, the amount of rotation that can be corrected by rotation of the substrate stage 43 is small. Therefore, if the amount of rotation of the substrate 6 is large, it is desirable to correct the rotation and hold again the substrate. If the substrate 6 is held again, alignment measurement is performed again. During this process, the surface position of the substrate 6 is desirably measured using a height measurement unit (not shown) that measures the surface position of the bonding surface of the substrate 6. This is because the thickness of the substrate 6 varies, and the surface position of the substrate 6 is important in accurately managing the gap between the substrate 6 (first member) and the die 51 (second member) in the bonding operation.

In a state in which the origin position, magnification, X- and Y-axis directions (rotations), and orthogonality of the substrate stage 43 are guaranteed using the reference plate 434, the position of the mounted substrate 6 with respect to the origin position, X-axis, and Y-axis of the substrate stage 43 can be measured. A semiconductor device is arranged in each of the plurality of regions of bonding targets on the substrate 6. The plurality of regions of bonding targets on the substrate 6 are normally arranged at a predetermined period. In general, these semiconductor devices are arrayed periodically at nano-level accuracy. For this reason, in alignment measurement that is a decision process of deciding the positions of the plurality of regions of bonding targets on the substrate 6, the positions of all regions with the semiconductor devices arranged need not be measured. For example, the positions of feature points of semiconductor devices arranged in three or more regions (sample regions) selected from the plurality of regions can be measured. Then, the (actual) positions of the plurality of semiconductor devices can be decided by statistical processing based on the result of measurement and the designed array information of the plurality of semiconductor devices (the plurality of regions). Alignment information indicating the (actual) positions of the plurality of semiconductor devices (the plurality of regions) can be decided as, for example, the origin position of the repetitive array of the plurality of semiconductor devices, the amounts of rotation in the X-and Y-axis directions, the orthogonality of the X-and Y-axes, and the magnification error of the repetitive period.

The substrate chuck 433 desirably comprises a mechanism that adjusts the temperature of the substrate 6. This is because the thermal expansion coefficient of a silicon substrate is 3 ppm/° C., and if the temperature of a 300-mm substrate rises by 1° C., the position moves by 150 mm×0.000003×0.00045 mm=450 nm at the outermost periphery. If the positions of the plurality of regions of bonding targets change after the alignment measurement (decision process), the die 51 cannot be bonded to each region of the substrate 6 at high accuracy. Hence, it is desirable to adjust the temperature of the substrate 6 at an accuracy of ±0.1° C. or less.

Note that if the substrate 6 is an interposer in which wirings are formed, not the array of semiconductor devices but the array of repetitively formed wirings is measured. Also, if the substrate 6 has no pattern, alignment measurement (decision process) is not executed.

The operation of the substrate 6 that is the first member has been described above. Next, the operation of the die 51 that is the second member operated in parallel will be described.

In step S2001, a dicing frame in which dies diced by a dicer are arrayed on a dicing tape is loaded into the bonding apparatus BD. If a foreign substance adheres to the bonding surface, a bonding failure may occur. Hence, the dicing frame can be transported in a container in which closeness is high and cleanliness is kept high. To increase the cleanliness, the dies on the dicing frame may be cleaned in the internal space of the bonding apparatus BD. The rotational direction and the shift position of the dicing frame can roughly be positioned by a prealignment unit (not shown) based on the outer shape of the dicing frame.

In step S2002, the die 51 is picked up by the pickup head 31. More specifically, the controller 441 moves the pickup head 31 and the release head 32 to the position of the die 51 to be picked up. While grasping or holding the die 51 by the pickup head 31, the controller 441 causes the release head 32 to peel the die 51 from the dicing tape.

In step S2003, the controller 441 controls the pickup head 31 to transfer the die 51 to the bonding head 423. The bonding head 423 can suck and hold the die 51 by the suction mechanism 424. When picking up the die 51 in step S2002, the semiconductor device surface of the die 51 is on the side of the pickup head 31. On the bonding head 423, however, the die 51 is held such that the semiconductor device surface is on the side opposite to the bonding head 423. The transfer can be performed by moving the pickup head 31 to the position of the bonding head 423. Alternatively, the transfer may be performed by relaying the die 51 by one or more holders between the pickup head 31 and the bonding head 423. Also, a preprocess for bonding can be executed halfway through the transfer. The preprocess can comprise, for example, a cleaning process of the die 51. Also, in a case of bonding using an adhesive, the preprocess can comprise a process of applying the adhesive. In a case of hybrid bonding, the preprocess can comprise a process of activating the surface of the die 51.

By the above-described operation, a state in which the substrate 6 that is the first member is held by the substrate chuck 433 and the die 51 that is the second member is held by the bonding head 423 is obtained.

Subsequently, in step S1003, the position of the die 51 held by the bonding head 423 is measured. More specifically, the controller 441 drives the substrate stage 43 so that the feature point of the die 51 falls within the field of view of the die observation camera 431. The feature point can be an element pattern or an alignment mark on the die bonding surface 51a. Alternatively, all or part of the measured outer dimensional shape of the die 51 may be handled as a feature point. Focus adjustment can be performed by, for example, the focus adjustment mechanism of the die observation camera 431. Alternatively, focus adjustment may be performed by Z-driving the die 51 by the Z-driving mechanism of the bonding head 423. Alternatively, focus adjustment may be performed by driving the die observation camera 431 in the Z direction by the Z-driving mechanism of the substrate stage 43 on which the die observation camera 431 is mounted.

Here, in a semiconductor manufacturing process, for alignment, an alignment mark is formed on a scribe line. However, the alignment mark can be removed from the die in dicing. Hence, the die 51 has no alignment mark in many cases. Hence, the position of the die 51 can be measured using, as a feature point, the termination of the array of pads or bumps arranged on the die bonding surface 51a, a region whose position can be specified because it has an aperiodic array, or the outer shape of the die 51. The controller 441 can measure the position of a feature point by measuring the position of a projected image of the feature point in a captured image with respect to the center of the captured image acquired by image capturing by the die observation camera 431. In step S1003, a plurality of feature points in the die 51 are measured, thereby measuring the amount of rotation of the die 51. To measure a plurality of feature points, the measurement may be performed by sequentially positioning the substrate stage 43 to a plurality of positions. Alternatively, the field of view of the die observation camera 431 may be made sufficiently wide, and the positions of a plurality of feature points may be measured in the field of view.

The rotation of the die 51 can be corrected by rotating the substrate stage 43 at the time of bonding. However, since the measurement range of the interferometer in the rotational direction is narrow, if the amount of rotation of the die 51 is large, it is desirable to correct the rotation and hold the die 51 again. If the die 51 is held again, the position of the die 51 needs to be measured again.

During this process, the surface position of the die 51 is desirably measured using a height measurement unit (not shown) that measures the surface position of the bonding surface 51a of the die 51. This is because the thickness of the die 51 varies, and the position of the surface of the die 51 is important in accurately managing the gap between the die 51 and the substrate 6 in the bonding operation. It is also desirable to measure the heights of a plurality of positions on the die 51 and adjust the posture of the die 51 or the substrate 6 by a tilt mechanism (not shown) at the time of bonding. The tilt mechanism can be provided in any one of the substrate stage 43, the substrate chuck 433, and the bonding head 423. In this process, the measured position of the feature point of the die 51 and the outer dimensional information of the die 51 itself are associated. In the association, the outer shape of the die 51 and the position of an element pattern or alignment mark on the die bonding surface 51a are associated. The controller 441 stores the associated information in a storage device inside or outside the bonding apparatus BD.

As described above, in step S1003, the controller 441 can measure an element pattern or alignment mark on the die bonding surface 51a, which is a feature point of the die 51, and all or part of the outer shape of the die 51. After that, the controller 441 associates the position of the feature point of the die 51 and the outer dimensional information of the die 51 itself and stores the information. Alternatively, in this process, instead of performing such measurement, the controller 441 may acquire these pieces of information about the die 51 to be bonded from the outside of the bonding apparatus BD and thus store the information in the bonding apparatus BD.

In step S1004, the controller 441 drives the substrate stage 43 such that the die 51 is located above a bonding target region on the substrate 6 based on the alignment information decided by the alignment measurement (decision process). Here, while measuring the position of the substrate stage 43 using the interferometer 422, the controller 441 feedback-controls the substrate stage 43 in real time, thereby accurately positioning the substrate stage 43. That is, in step S1002, the controller 441 can execute the decision process of deciding the positions of a plurality of regions by measuring the positions of regions (sample regions) selected from the plurality of regions on the substrate 6 using the substrate observation camera 421 (scope). Then, in step S1004, the controller 441 can control the bonding process based on (the alignment information indicating) the positions of the plurality of regions on the substrate 6.

Next, in step S1005, the controller 441 bonds the die 51 to the bonding target region on the substrate 6. More specifically, the controller 441 controls the lifting mechanism 450 that is a relative driving mechanism to perform the approximating operation of moving the bonding head 423 and the substrate stage 43 close to each other so as to bring the die 51 and the bonding target region on the substrate 6 into contact with each other. After the contact between the die 51 and the bonding target region on the substrate 6, the controller 441 controls the lifting mechanism 450 to perform the separating operation of moving the bonding head 423 and the substrate stage 43 away from each other.

In step S1006, the controller 441 determines whether bonding of the die 51 to all the plurality of regions of bonding targets on the substrate 6 is completed. Normally, several ten to several hundred semiconductor devices are formed on one substrate 6. Since a die is bonded to each semiconductor device, die bonding is repeated a plurality of times. If the die 51 is not bonded to all the regions of bonding targets on the substrate 6, the process advances to step S1007.

Note that here, the determination process in step S1006 is performed after step S1005. However, it is also possible to perform the determination process in step S1006 in advance (for example, at a timing before step S2002) and execute the die pickup operation in step S2002 in parallel during the process from step S1003 to step S1005. Also, when bonding a plurality of types of dies to one semiconductor device, after bonding of dies of one type is ended for all semiconductor devices on one substrate, and bonding of dies of the next type can start. In this case, dies of the next type are picked up in step S2002. At this time, a necessary process such as the loading operation of a dicing frame on which dies of the next type are mounted is executed.

In step S1007, the controller 441 determines the necessity of another alignment measurement in accordance with the situation of the bonding process. Here, in the bonding apparatus BD, the position of the substrate 6 may change due to the force applied to the substrate 6 when bonding the die 51 to the bonding target region on the substrate 6. In addition, if the die 51 and the substrate 6 are made of materials of different characteristics, warpage of the substrate 6 derived from the expansion coefficient difference between the die 51 and the substrate 6 may be caused by bonding. If the change of the position of the substrate 6 or the warpage of the substrate 6 occurs after the alignment measurement, it is impossible to accurately bond the die 51 to the bonding target region on the substrate 6.

The bonding process is a process of bonding the die 51 that is the second member to a plurality of regions of bonding targets on the substrate 6 that is the first member. This is a process shown by, for example, the flowchart of FIG. 4. The situation of the bonding process can comprise at least one of, for example, the progress of the bonding process, the state of the die 51 bonded to the substrate 6 in the bonding process, the state change of the substrate 6 in the bonding process, and the state change of the bonding mechanism 4 in the bonding process. In other words, the controller 441 can determine the situation of the bonding process based on at least one of, for example, the progress of the bonding process, the state of the die 51 bonded to the substrate 6 in the bonding process, the state change of the substrate 6 in the bonding process, and the state change of the bonding mechanism 4 in the bonding process.

The progress of the bonding process can be determined or specified based on, for example, information depending on the number of regions where the bonding is completed among the plurality of regions of bonding targets on the substrate 6. The information depending on the number of regions where the bonding is completed among the plurality of regions of bonding targets on the substrate 6 can be, for example, information indicating the number (n) of regions where the bonding is completed among the plurality of regions of bonding targets on the substrate 6. The number (n) can have correlation with the warpage of the substrate 6. Alternatively, the information depending on the number of regions where the bonding is completed among the plurality of regions of bonding targets on the substrate 6 can be, for example, the ratio (a×n/A) of the sum (a×n) of the areas (a) of regions where the bonding is completed among the plurality of regions of bonding targets to the area (A) of the surface of the substrate 6. This ratio can also have correlation with the warpage of the substrate 6.

The state of the die 51 bonded to the substrate 6 in the bonding process can be, for example, the position of the die 51 bonded to the substrate 6. The position of the die 51 bonded to the substrate 6 can be measured using the substrate observation camera 421 (scope). Alternatively, the state of the die 51 bonded to the substrate 6 in the bonding process can be, for example, the height of the die 51 bonded to the substrate 6. The height of the die 51 bonded to the substrate 6 can be measured using a height measurement unit (not shown) or the substrate observation camera 421 (scope).

The state change of the substrate 6 in the bonding process can be, for example, at least one of the change of the position of the substrate 6 and the deformation of the substrate 6. The deformation of the substrate 6 can be, for example, at least one of the change of the shape of the substrate 6 projected to the X-Y plane (horizontal surface) and the warpage of the substrate 6. These can be measured using the substrate observation camera 421 (scope).

The bonding mechanism 4 can be the whole or a part of the bonding apparatus BD. The bonding mechanism 4 can comprise, for example, the positioning mechanism PM and the bonding head 423. The state change of the bonding mechanism 4 in the bonding process is, for example, a state change that may affect the accuracy of bonding of the die 51 to the substrate 6. The state change of the bonding mechanism 4 in the bonding process is, for example, the state change of the substrate chuck 433 that holds the substrate 6. If the substrate chuck 433 is a vacuum chuck, the state change of the substrate chuck 433 can be a pressure change of a vacuum line for vacuum suction. The state change of the bonding mechanism 4 in the bonding process may include the state change of the positioning mechanism PM that positions the substrate 6. The state change of the positioning mechanism PM can comprise, for example, the change of the maximum value of the control deviation of the substrate stage 43.

The controller 441 may determine the situation of the bonding process based on log data (for example, the control deviation of the substrate stage 43) indicating the operation of the bonding mechanism 4 in the bonding process. The controller 441 can decide to re-execute alignment measurement (decision process) if, for example, the log data indicates an abnormality (the maximum value of the control deviation of the substrate stage 43 exceeds a determination threshold).

Alternatively, the controller 441 can measure the position of a specific location of the substrate 6 using the substrate observation camera 421 every time the die 51 is bonded to the substrate 6 in parallel to the measurement process for measuring, using the die observation camera 431, the position of the die 51 held by the bonding head 423. The controller 441 can then determine the situation of the bonding process based on the change of the position of the specific location (feature point) of the substrate 6. The specific location of the substrate 6 can be a location of the substrate 6, which is arranged in the field of view of the substrate observation camera 421 when measuring, using the die observation camera 431, the position of the die 51 held by the bonding head 423. Alternatively, the specific location of the substrate 6 can be a location of the substrate 6, which enters the field of view of the substrate observation camera 421 in a path for moving the substrate stage 43 to capture, using the die observation camera 431, an image of the die 51 held by the bonding head 423. This operation is advantageous for suppressing a delay (that is, a decrease of throughput) of the bonding process caused by the process for determining the necessity of another alignment measurement.

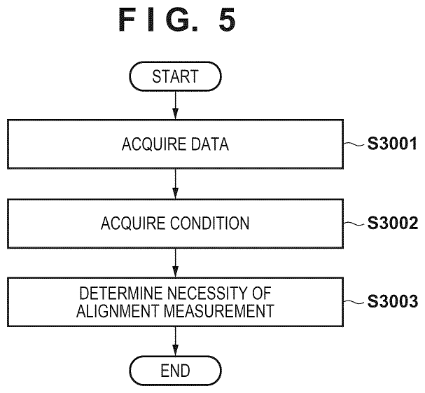

FIG. 5 exemplarily shows the procedure of the determination process in step S1007. In step S3001, the controller 441 acquires determination data used to determine the necessity of alignment measurement. The determination data can be data used to specify the situation of the bonding process. More specifically, the determination data can be data used to determine at least one of the progress of the bonding process, the state of the die 51 bonded to the substrate 6 in the bonding process, the state change of the substrate 6 in the bonding process, and the state change of the bonding mechanism 4 in the bonding process.

In step S3002, the controller 441 acquires a condition to determine the necessity of alignment measurement, and in step S3003, the controller determines the necessity of another alignment measurement based on the acquired condition. The condition can be a condition that, for example, alignment measurement is re-executed if the number of regions where bonding is completed among the plurality of regions of bonding targets on the substrate 6 exceeds the determination threshold. Alternatively, the condition can be a condition that alignment measurement is re-executed if the ratio (a×n/A) of the sum (a×n) of the areas (a) of regions where bonding is completed among the plurality of regions of bonding targets to the area (A) of the surface of the substrate 6 exceeds the determination threshold. Alternatively, the condition can be a condition that alignment measurement is re-executed if the error (a deviation from a target position) of the position of the die 51 bonded to the substrate 6 exceeds the determination threshold. Alternatively, the condition can be a condition that alignment measurement is re-executed if the height (a deviation from a defined height) of the position of the die 51 bonded to the substrate 6 exceeds the determination threshold. Alternatively, the condition can be a condition that alignment measurement is re-executed if at least one of the change of the position of the substrate 6 and the deformation of the substrate 6 exceeds the determination threshold. Alternatively, the condition can be a condition that it is determined to re-execute alignment measurement again if the amount of the state change of the bonding mechanism 4 exceeds the determination threshold. Alternatively, the controller 441 can re-execute alignment measurement if the position of a specific location of the substrate 6 measured in parallel to the measurement process for measuring the position of the die 51 changes beyond the determination threshold.

Hereinafter, the description will be made with reference to FIG. 4 again. In step S1008, the controller 441 advances to a step according to the determination result in step S1007, that is, the result of determining the necessity of another alignment measurement. More specifically, upon determining that another alignment measurement is necessary, the controller 441 advances to step S2002 via step S1009. Upon determining that another alignment measurement is unnecessary, the controller 441 advances to step S2002 without passing through step S1009.

In step S1009, the controller 441 executes alignment measurement, like step S1002. Summarizing the above, in steps S1007 and S1008, the controller 441 determines to re-execute alignment measurement in accordance with the situation of the bonding process.

In step S2002, the pickup head 31 picks up the next die 51 to be bonded. More specifically, the controller 441 moves the pickup head 31 and the release head 32 to the position of the die 51 to be picked up next. While grasping or holding the die 51 by the pickup head 31, the controller 441 causes the release head 32 to peel the die 51 to be bonded next from the dicing tape. Steps S2003 and steps S1003 to S1005 are executed below.

In step S1006, upon determining that the bonding operation of the die 51 is performed for all the plurality of regions of bonding targets on the substrate 6, in step S1010, the controller 441 controls a substrate conveyance apparatus (not shown) to unload the substrate 6 from the bonding apparatus BD. The unloaded substrate is returned to the original container such as a FOUP or returned to another container. In general, since the thickness of the substrate changes, and the gap between substrates needs to be made wider as compared to the substrates before bonding, the unloaded substrate is returned to another container.

A bonding process for one substrate 6 has been described above. When performing the bonding process for a plurality of substrates 6, the above-described bonding process is performed for each substrate 6.

Note that in general, since the number of dies on the dicing frame and the number of dies to be bonded to the substrate are different, loading of the substrate and loading of the dicing frame are not synchronized. If dies on a dicing frame run out before completion of die bonding to a plurality of regions on one substrate, the next dicing frame is loaded. If dies remain on a dicing frame even after completion of die bonding to a plurality of regions on one substrate, the dies are used for bonding to the next substrate.

According to the above-described process, alignment measurement is re-executed even in a case where the situation of the bonding process changes, for example, the position of the substrate changes or the substrate warps after alignment measurement (decision process). It is therefore possible to correctly bond a die to a target position on a substrate.

A method of manufacturing an article (for example, a semiconductor IC element, a liquid crystal display element, or a MEMS) using the above-described bonding apparatus BD will be explained. The article manufacturing method is suitable for manufacturing an article, for example, a microdevice such as a semiconductor device or an element having a fine structure. The article manufacturing method according to the embodiment comprises a bonding step of bonding a second member to a first member using the above-described bonding apparatus to obtain a bonded article, and a processing step of processing the bonded article obtained by the bonding step, thereby obtaining an article. Further, the manufacturing method comprises other known processes (for example, probing, dicing, bonding, and packaging). The article manufacturing method according to the embodiment is advantageous in at least one of the performance, quality, productivity, and production cost of the article, as compared to conventional methods.

While the present disclosure has been described with reference to embodiments, it is to be understood that the present disclosure is not limited to the disclosed embodiments. The scope of the following claims is to be accorded the broadest interpretation so as to encompass all such modifications and equivalent structures and functions.

This application claims the benefit of Japanese Patent Application No. 2024-156836, filed Sep. 10, 2024, which is hereby incorporated by reference herein in its entirety.

What is claimed is:

1. A bonding apparatus configured to execute a bonding process of bonding a second member to a plurality of regions of a first member, comprising:
a scope;
a bonding mechanism configured to bond each of a plurality of second members to one of the plurality of regions; and
a controller configured to execute a decision process of deciding positions of the plurality of regions by using the scope to measure a position of a selected region among the plurality of regions and to control the bonding process based on the positions of the plurality of regions,
wherein the controller decides to re-execute the decision process in accordance with a situation of the bonding process.

2. The apparatus according to claim 1, wherein
the controller determines the situation of the bonding process based on at least one of: a progress of the bonding process, a state of the second member bonded to the first member in the bonding process, a state change of the first member in the bonding process, and a state change of the bonding mechanism in the bonding process.

3. The apparatus according to claim 1, wherein
the controller determines the situation of the bonding process based on information depending on the number of regions where bonding is completed among the plurality of regions.

4. The apparatus according to claim 1, wherein
the controller determines the situation of the bonding process based on a ratio of a sum of areas of regions where bonding is completed among the plurality of regions to an area of a surface of the first member.

5. The apparatus according to claim 1, wherein
the controller determines the situation of the bonding process based on a position of the second member bonded to the first member.

6. The apparatus according to claim 1, wherein
the controller determines the situation of the bonding process based on a height of the second member bonded to the first member.

7. The apparatus according to claim 1, wherein
the controller determines the situation of the bonding process based on at least one of a change of a position of the first member and deformation of the first member in the bonding process.

8. The apparatus according to claim 1, wherein
the bonding mechanism comprises a chuck configured to hold the first member, and
the controller determines the situation of the bonding process based on a state of the chuck.

9. The apparatus according to claim 1, wherein
the bonding mechanism comprises a positioning mechanism configured to position the first member, and
the controller determines the situation of the bonding process based on a state of the positioning mechanism.

10. The apparatus according to claim 1, wherein
the controller determines the situation of the bonding process based on log data indicating an operation of the bonding mechanism in the bonding process.

11. The apparatus according to claim 10, wherein
the controller decides to re-execute the decision process if the log data indicates an abnormality.

12. The apparatus according to claim 1, further comprising a second scope,
wherein the bonding mechanism comprises a bonding head configured to hold the second member to be bonded next among the plurality of second members,
the controller measures a position of a specific location of the first member using the scope every time the second member is bonded to the first member in parallel to a measurement process for measuring, using the second scope, a position of the second member held by the bonding head, and
the controller determines the situation of the bonding process based on a change of the position of the specific location of the first member.

13. The apparatus according to claim 12, wherein
the specific location is a location of the first member, which is arranged in a field of view of the scope when measuring, using the second scope, the position of the second member held by the bonding head.

14. An article manufacturing method comprising:
bonding a second member to a first member using a bonding apparatus defined in claim 1 to obtain a bonded article; and
processing the bonded article to obtain an article.

15. A bonding method comprising:
executing a decision process of deciding positions of a plurality of regions of a first member by measuring, using a scope, a position of a selected region among the plurality of regions;
executing a bonding process of bonding one of a plurality of second members to each of the plurality of regions based on the positions of the plurality of regions decided by the decision process; and
re-executing the decision process in accordance with a situation of the bonding process.

16. An article manufacturing method comprising:
bonding a second member to a first member in accordance with a bonding method to obtain a bonded article,
wherein the bonding method comprises:
executing a decision process of deciding positions of a plurality of regions of the first member by using a scope to measure a position of a selected region among the plurality of regions;
executing a bonding process of bonding one of a plurality of second members to each of the plurality of regions based on the positions of the plurality of regions decided by the decision process; and
re-executing the decision process in accordance with a situation of the bonding process; and
processing the bonded article to obtain an article.
